(19) United States
(12) Patent Application Publication
(10) Pub. No.: US 2025/0218513 A1
(43) Pub. Date: Jul. 3, 2025

(54) ELECTRONIC CIRCUIT ADAPTED FOR CHARGING OR READING A FLOATING-GATE MEMORY STRUCTURE

(71) Applicant: The Swatch Group Research and Development Ltd, Marin (CH)

(72) Inventors: Arnaud CASAGRANDE, Bôle (CH); Jean-Luc AREND, Corcelles (CH); Alexandre ACOVIC, Lonay (CH)

(73) Assignee: The Swatch Group Research and Development Ltd, Marin (CH)

(21) Appl. No.: 18/982,009

(22) Filed: Dec. 16, 2024

(30) Foreign Application Priority Data
Dec. 29, 2023 (EP) 23220729.0

(51) Int. Cl. G11C 16/04; H10B 41/41; H10D 30/60

(52) U.S. Cl. CPC G11C 16/045; H10B 41/41; H10D 30/601

(57) ABSTRACT

An electronic circuit having a floating-gate memory structure, which includes from a first input terminal (T) a first MOS type transistor (1) with a large floating gate (FG), and from a second input terminal (B) a second MOS type transistor (2) with a smaller floating gate (FG) than the first MOS transistor (1). The first MOS transistor (1) is connected in series via its floating gate (FG) to the floating gate (FG) of the second MOS transistor (2). The electronic circuit is arranged so as to read and charge the floating-gate memory structure. The first MOS transistor is converted to act directly as a read transistor of the floating-gate memory structure.

### CROSS REFERENCE TO RELATED APPLICATIONS

This application claims priority to European Patent Application No. 23220729.0 filed Dec. 29, 2023, the entire contents of which are incorporated herein by reference.

### TECHNICAL FIELD OF THE INVENTION

The present invention relates to an electronic circuit adapted to charge or read a floating-gate memory structure forming part of the electronic circuit.

### TECHNOLOGICAL BACKGROUND

As shown schematically in FIG. 1, the electronic circuit comprises at least one memory structure of the electrically-erasable (EE) type. The memory structure may comprise at least one floating-gate MOS transistor FG to define a capacitor. However, this floating-gate memory structure is composed instead of a first MOS transistor 1 with a coupling capacitance Cc and a second MOS transistor 2 with a coupling capacitance Ct. Each MOS transistor is made in the same semiconductor substrate, which may be of the P-type or N-type. In general, the two transistors 1 and 2 are made in the same P-type semiconductor substrate to define PMOS transistors with all the other elements of the integrated electronic circuit. The two floating-gate PMOS transistors 1 and 2 are connected to each other in series by their common floating gate FG.

In this memory structure of the electronic circuit shown in FIG. 1, the floating gate denoted FG is charged by tunnel effect by coupling a programming voltage applied at a first input terminal T of the first PMOS transistor 1 or at a second input terminal B of the second PMOS transistor 2. In general, tunnel-effect charging is applied via the second input terminal B of the second PMOS transistor 2, which is smaller than the first PMOS transistor 1. The voltage thus programmed on this floating gate FG is read afterwards by the PMOS read (T_read) transistor 3, whose gate is connected to the floating gate FG. The overall structure, which is shown in the asymmetrical mode in FIG. 1, uses PMOS-type transistors 1 and 2 to implement first and second capacitors 1 and 2 with capacitances Cc and Ct. The structure is generally implemented in the differential mode. In order to maximise coupling between the first terminal T and the floating gate FG, the PMOS read transistor 3 (with a parasitic capacitance) and the second PMOS tunnel-effect transistor 2 with the capacitance Ct are sized as small as possible compared with the first PMOS coupling Cc transistor 1. Consequently, for a given size of the Cc-Ct-T_read set, the read offset, which is the offset between the threshold voltage and the measured current, is inversely proportional to the size of the PMOS read transistor. Since the memorised voltage decreases over time, this large offset limits the memory retention time, adding statistical uncertainty to the memorised voltage, which is a drawback of such a memory structure.

### SUMMARY OF THE INVENTION

To this end, the present invention relates to an electronic circuit with a floating-gate memory structure by configuring one of the MOS-type transistors with coupling capacitance with a large floating gate in the form of a MOS-type read transistor to avoid using another specific read transistor as described in the independent claim 1.

Particular embodiments of the electronic circuit with a floating-gate memory structure are defined in the dependent claims 2 to 13.

An advantage of the present invention is that a MOS transistor is configured to implement a large capacitor with a coupling capacitance of the floating-gate memory structure. It is then simpler to interface this MOS transistor in the read mode by means of protection transistors, since the parasitic capacitive charges of these protection transistors do not influence the coupling of the input terminals of the memory structure at the floating gate as such. As the size of the MOS read transistor (to implement a capacitor with a coupling capacitance Cc) is now large, the read offset is significantly reduced. In addition, the elimination of the small read transistor of the prior art substantially increases the capacitive coupling according to the given capacitive ratio of the two transistors implementing the two capacitors.

One advantage of the present invention is that it is possible to reduce offset problems in reading an electrically-erasable permanent memory structure in a single poly-silicon substrate technology.

### BRIEF DESCRIPTION OF THE FIGURES

The aims, advantages and features of an electronic circuit adapted to charge or read a floating-gate memory structure forming part of the electronic circuit will become clearer in the following non-limiting description with reference to the drawings wherein:

FIG. 1 is a schematic representation of a floating-gate memory structure according to the prior art,

FIG. 2 is a schematic representation of a floating-gate memory structure of an electronic circuit adapted to charge or read said structure of the present invention wherein a MOS type read transistor implementing a coupling capacitor is used

FIG. 3 is a more detailed representation of a first embodiment of an electronic circuit adapted to charge or read at least one floating-gate memory structure of said electronic circuit, and

FIG. 4 is a more detailed representation of a second embodiment of an electronic circuit adapted to charge or read two floating-gate memory structures inversely connected in parallel with said electronic circuit.

### DETAILED DESCRIPTION OF THE INVENTION

The electronic circuit having a floating-gate memory structure of the present invention allows having an improved coupling for reading or charging the floating-gate memory structure. In addition, during operation of the circuit, it is observed that there are fewer problems with offsets when reading such a memory structure.

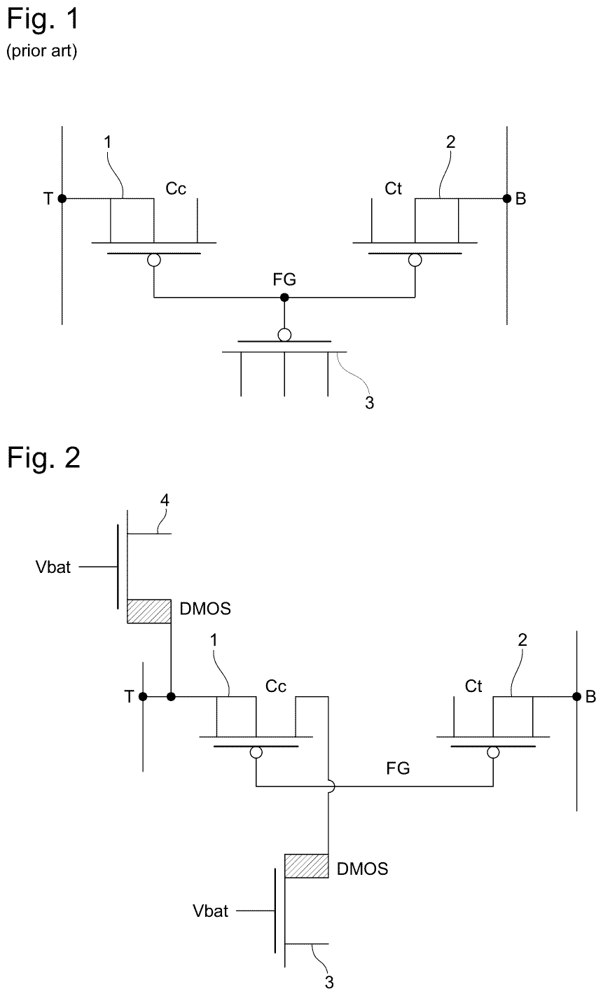

FIG. 2 primarily shows in schematic form the floating-gate memory structure of the electronic circuit simplified compared with the prior art shown in FIG. 1 described hereinabove. The first MOS transistor 1 with a large coupling capacitance Cc implements a first capacitor. In this manner, it is simple to interface this transistor in the read mode also using protection transistors that are not shown, as the parasitic capacitive charges of these protection transistors have absolutely no influence on the coupling of the first input terminal T or of the second input terminal B on the floating gate FG.

Since the electronic circuit with a floating-gate memory structure is preferably integrated in a P-type silicon substrate, the first transistor 1 is a PMOS read transistor for implementing a first capacitor. The source and substrate terminals of this first PMOS transistor 1 are connected to the first input terminal T, and the drain terminal is connected, in order to read the information, to a MOS type read transistor with the floating gate FG previously programmed at a defined voltage. Programming of the floating gate FG will be carried out mainly via a second PMOS transistor 2 with a coupling capacitance Ct. A programming voltage of up to nearly 8 V or more will enable a defined voltage to be programmed via the second small Ct PMOS transistor 2 by tunnel effect on the floating gate FG or using the hot electron injection effect. In the present case, programming by tunnel effect through at least one insulating layer will be used instead to charge the floating gate FG common to the two PMOS transistors 1 and 2, implementing the two capacitors Cc and Ct.

As the first PMOS read transistor 1 is large, the read offset is significantly reduced. The second small PMOS transistor 2 with a coupling capacitance Ct is connected in the same integrated circuit to the floating gate FG of the first PMOS transistor 1 with a large coupling capacitance Cc. This second PMOS transistor 2 is made with the source and the substrate connected to the second input terminal B, while the drain is left unconnected. In addition, with the elimination of the previous read transistor of the prior art, this allows forming a differential read pair and substantially increasing the coupling at the given capacitive ratio Cc/Ct.

Thus, the first PMOS transistor 1 of the memory structure is directly a transistor for reading the state-of-charge of the floating gate of the memory structure in order to avoid the use of an original read transistor as shown in FIG. 1, having an associated parasitic capacitance, and so as to increase the coupling factor of a programming voltage (Vprog) and thus to reduce the value of the programming voltage (Vprog) required to obtain a given floating-gate voltage (FG).

For information, some values can be given for the size of the PMOS transistors 1 and 2 used to implement two capacitors and for the different battery voltages Vbat, power supply voltages Vdd and programming voltages Vprog of the floating-gate memory structure FG. The first PMOS transistor 1 may be made over a width w equal, for example, to 2.24 μm and over a length l equal, for example, to 1.75 μm, which gives a surface area at the floating gate in the range of 3.92 μm² approaching 4 μm². On the other hand, the second PMOS transistor 2 may be made over a width w equal, for example, to 0.65 μm and over a length l equal, for example, to 0.5 μm, which gives a surface area at the floating gate in the range of 0.325 μm². The surface ratio between the two PMOS transistors 1 and 2 implementing two integrated capacitors Cc and Ct of the electronic circuit is therefore more than 10 times and in this case even 12 times greater. This shows the large dimensional difference between the first PMOS transistor and the second PMOS transistor. The supply voltage Vdd of the integrated electronic circuit with all these components required to read and charge the floating-gate memory structure that forms part of the electronic circuit can be defined as being in the range of 1.2 V, while the battery voltage Vbat used to bias some transistors connected to the first and second input terminals T and B of the memory structure can be in the range of 3.6 V. The programming voltage Vprog of the memory structure, in particular via the second input terminal B by the second PMOS transistor 2, may be in the range of 7.4 V or even up to almost 9 V, during the programming phase, for a programming time of up to 100 ms per pulse. Of course, once programming has been performed on the floating gate FG of the memory structure, the programming voltage terminal Vprog could be left floating. The battery voltage could be lowered to 1.2 V equal to the supply voltage Vdd. In some cases, when the floating gate FG is charged, the supply voltage Vdd can even be placed at the level of the ground Vss temporarily in the reading phase of the floating-gate voltage FG.

It should also be noted that in general, when the programmed floating-gate voltage becomes sufficiently low (typically in the 1 mV range), the tunnel-effect current of a thin oxide becomes comparable to the tunnel-effect current of a thick oxide at 1 V. If the read-out operation is performed quickly (by exposing the gate to VT only for a very short read-out time, or by compensating with a similar exposure to −VT), thin-oxide devices could be used for long-term retention. Self-zeroing differential sense amplifiers would then be required to correctly detect the very small voltage difference of the binary cell. The advantage is that a typical programming voltage of 5 V is then sufficient to program the structure.

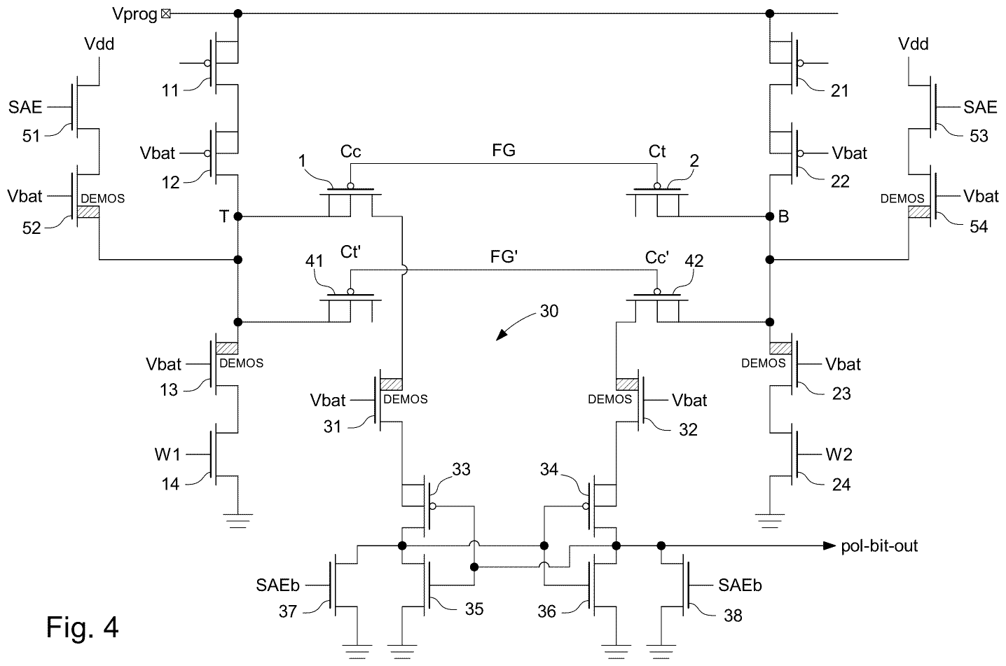

FIG. 2 also shows an NMOS transistor 3 with a power supply potential Vbat on its gate at the output of the PMOS read transistor 1, and another NMOS transistor 4 connected to the first input terminal T of the new read transistor 1. These two transistors 3 and 4 may also be N DEMOS (“Drain-Extended-MOS”) type transistors. Thanks to these DEMOS transistors, it is possible to protect the latch explained in FIG. 4 hereinafter and access to the supply voltage Vdd from the programming voltage Vprog, which may be higher during a programming phase. Special DEMOS transistors with a drain surrounded by a 0.3 μm Nwell well overlap have been used to implement the cascode transistors, in order to increase reverse breakdown and avoid the corresponding undesirable breakdown current to Vss and to allow a voltage Vprog of up to +9V.

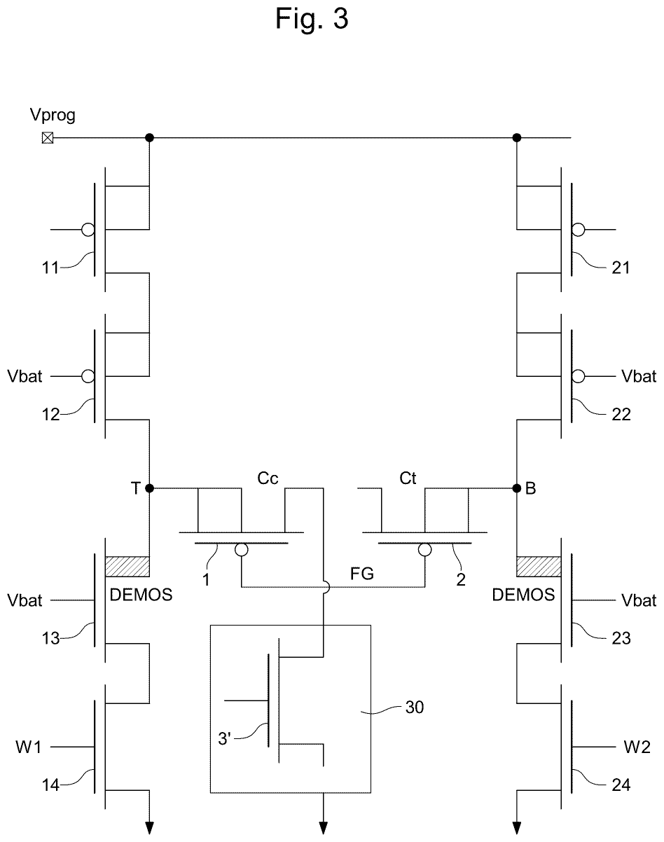

FIG. 3 shows a first embodiment of the electronic circuit for reading or charging a floating-gate memory structure forming part of the electronic circuit. The memory structure described with reference to FIG. 2 hereinabove is now clearly shown in connection with transistors cascode-connected from the input terminals T and B. The two PMOS transistors 1 and 2 of the memory structure are shown in series between the two input terminals T and B. The first large PMOS transistor 1 with a coupling capacitance Cc and the second PMOS transistor 2 with a coupling capacitance Ct are connected via the common floating gate FG.

In general, when using the integrated electronic circuit with the floating-gate memory structure FG, there is first of all a memory structure programming phase, and after this memory structure programming, there are, on request, one or more successive reading phases staggered over time of the reading state of the floating-gate memory structure FG. In each read phase with the memory structure programmed, the first large PMOS transistor 1 can act as a transistor for reading the charge accumulated on the floating gate. In this respect, a read unit 30 is connected to the drain of this PMOS transistor so as to determine the state-of-charge of the floating-gate memory structure. For simplicity, a complementary NMOS-type transistor 3′ is shown with its drain connected to the drain of the first PMOS transistor 1 implementing a first capacitor Cc in the read phase of the charge on the floating gate FG in the read unit 30. This transistor 3′ may also be of the same type as the DEMOS transistor 3 in FIG. 2.

The electronic circuit shown in FIG. 3 is now described with all the transistors required for operation thereof, whether for programming the memory structure or for reading or charging the floating-gate memory structure. As indicated hereinabove, pairs of transistors connected in cascode from the input terminals T and B of the floating gate capacitors FG are preferably used. First of all, to program the floating gate FG, two PMOS-type transistors 21 and 22 connected in series connect a programming voltage Vprog terminal on one side and the second input terminal B of the floating-gate memory structure on the other. In this case, a programming of the floating gate FG can be performed through the second PMOS transistor 2 with a small capacitance Ct by tunnel effect. The first PMOS transistor 21 is connected via the source and the substrate to the programming terminal Vprog, while the drain of the first PMOS transistor 21 is connected to the source and the substrate of the second PMOS transistor 22, whose gate is biased by a battery voltage Vbat. The first PMOS transistor 21 acts as a switch to connect the programming terminal to the second input terminal B. If the voltage on the gate of the first PMOS transistor is at least at a voltage equivalent to or lower than the battery voltage Vbat, this means that both the first PMOS transistor 21 and the second PMOS transistor 22 are made conductive in order to be able to perform programming of the floating gate FG of the memory structure via the second PMOS transistor 2 implementing a second capacitor of the memory structure.

Two other PMOS transistors 11 and 12 connected in series connect on one side the programming voltage terminal Vprog, and on the other side the first input terminal T of the floating-gate memory structure. The first PMOS transistor 11 is connected via the source and substrate to the programming terminal Vprog, while the drain of the first PMOS transistor 11 is connected to the source and substrate of the second PMOS transistor 12, whose gate is biased by a battery voltage Vbat. Unlike the first PMOS transistor 21, the first PMOS transistor 11 is made non-conductive so that it has no connection with the programming voltage terminal Vprog. The drain of the second PMOS transistor 12 is connected to the first input terminal T of the first PMOS transistor 1 implementing a first capacitor.

From the first input terminal T of the memory structure, a pair of NMOS type transistors in series is provided. The third NMOS transistor 13 is connected via its drain to the first input terminal T, while the source terminal is connected to the drain terminal of the fourth NMOS transistor 14, whose source terminal is preferably connected directly to the ground. The gate of the third NMOS transistor 13 is biased by a battery voltage Vbat, while the gate of the fourth NMOS transistor 14 is controlled by a first control signal W1.

From the second input terminal B of the memory structure, another pair of NMOS type transistors in series is provided. The third NMOS transistor 23 is connected via its drain to the second input terminal B, while the source terminal is connected to the drain terminal of the fourth NMOS transistor 24, whose source terminal is preferably connected directly to ground. The gate of the third NMOS transistor 23 is biased by a battery voltage Vbat, while the gate of the fourth NMOS transistor 24 is controlled by a second control signal W2.

Preferably, the third NMOS transistors 13 and 23 are DEMOS (Drain-Extended-MOS) type transistors.

FIG. 4 shows a second embodiment of an electronic circuit adapted to charge or read two floating-gate memory structures FG and FG′ inversely connected in parallel of said electronic circuit. The operating principle of this type of memory structure is based on a differential structure of two floating gates FG and FG′, each being connected to two PMOS transistors in series, namely a first PMOS transistor 1 with a large coupling capacitance Cc connected to the first input terminal T, and a second PMOS transistor 2 with a small coupling capacitance Ct adapted for programming the first floating gate FG by tunnel effect through the second input terminal B. The first large PMOS transistor 1 can be directly adapted to serve as a first PMOS type read transistor by connecting its drain terminal to a drain terminal of a first NMOS type transistor 31 of the read unit 30. Of course, this first NMOS transistor 31 may advantageously be a first DEMOS transistor.

A third PMOS transistor 42 with a large coupling capacitance Cc′ is connected to the second input terminal B, and can be adapted to serve as a second PMOS type read transistor by connecting its drain terminal to a drain terminal of a second NMOS type transistor 32 of the read unit 30. Of course, this second NMOS transistor 32 of the read unit 30 may advantageously be a second DEMOS transistor. A fourth PMOS transistor 41 with a small coupling capacitance Ct′ is connected to the first input terminal T, and can be adapted for programming the second floating gate FG′ by tunnel effect through the first input terminal T.

The PMOS coupling Cc, Ct, Cc′ and Ct′ transistors 1, 2, 41, 42 may preferably be made as thick oxide PMOS transistors (for example with a thickness in the range of 60 Angstrom). For this purpose, the source and gate connections are preferably used, as the drain connection is not used if the transistor is not used as a sense transistor.

It should also be noted that the unused drain terminal of the PMOS transistor making the capacitor with the largest coupling capacitance Cc and Cc′ can be used to create a large read transistor, and thus eliminate the very small standard read transistor as in the prior art. In addition, the coupling function of the MOS transistor with the largest capacitance is maximised by allowing eliminating the parasitic charge of the original read transistor. As the read transistor is enlarged, the offset error of the electronic read circuit is reduced. This allows increasing the retention time of the memory in which the floating gate potentials FG and FG′ slowly decrease over time through leakage. In addition, as coupling to the floating gate FG/FG′ of the programming pulse (high voltage applied at the input terminals T or B) is improved, the programmed voltage is also maximised.

It should also be noted that the PMOS, DEMOS and NMOS transistor pairs 11, 12, 13, 14, 21, 22, 23, 24, which are identical to those already described with reference to FIG. 3, will not be described again with reference to FIG. 4.

As one could also notice in FIG. 4, the read unit 30 also comprises, under the first and second transistors 31 and 32, a latch assembly capable of outputting a signal denoted pol_bit_out, which provides information about the programming state on each of the floating gates FG and FG′.

To this end, a third PMOS transistor 33 is provided, whose source and substrate terminals are connected to the source terminal of the first NMOS or DEMOS transistor 31, and whose drain terminal is connected to a drain terminal of a fifth NMOS transistor 35. The fifth transistor 35 has its source terminal directly connected to the ground. The gate terminals of the third and fifth transistors 33 and 35 are connected to each other, which allows forming a first inverter.

A fourth PMOS transistor 34 is also provided, whose source and substrate terminals are connected to the source terminal of the second NMOS or DEMOS transistor 32, and whose drain terminal is connected to a drain terminal of a sixth NMOS transistor 36. The sixth transistor 36 has its source terminal directly connected to the ground. The gate terminals of the fourth and sixth transistors 34 and 36 are connected to each other, which allows forming a second inverter.

It should also be noted that the gate terminals of the third transistor 33 and of the fifth transistor 35 are connected to the drain terminal of the fourth transistor 34 and to the drain terminal of the sixth transistor 36, which allows outputting at least one pol-bit-out output signal. Similarly, the gate terminals of the fourth transistor 34 and of the sixth transistor 36 are connected to the drain terminal of the third transistor 33 and to the drain terminal of the fifth transistor 35.

It is also provided for connecting a first NMOS transistor 37 of a quiescent mode to the fifth NMOS transistor 35. The drain terminal of the first transistor 37 of the quiescent mode, whose source terminal is connected to the ground, is connected to the drain terminal of the fifth transistor 35. Similarly, it is provided for connecting a second NMOS transistor 38 of a quiescent mode via its drain terminal to the drain terminal of the sixth NMOS transistor 36. The source terminal of this second NMOS transistor 38 is connected to the ground. In this manner, if a quiescent mode is desired, the gate terminal of the first and second transistors 37 and 38 is at a sufficient voltage supplied by the SAEb signal to make them conductive and thus switch into the quiescent mode.

It is also provided for connecting a first NMOS transistor 51 between a supply voltage Vdd and the first input terminal T of the memory structure via a drain terminal to a supply voltage terminal Vdd and via a source terminal to a drain terminal of a second DEMOS transistor 52, whose source terminal is connected to the first input terminal T. The first transistor 51 is controlled at its gate terminal by an SAE signal, while the gate terminal of the second transistor 52 is controlled by the battery voltage signal Vbat.

Similarly, it is also provided for connecting a third NMOS transistor 53 between a supply voltage Vdd and the second input terminal B of the memory structure via a drain terminal to a supply voltage terminal Vdd and via a source terminal to a drain terminal of a fourth DEMOS transistor 54, whose source terminal is connected to the second input terminal B. The third transistor 53 is controlled at its gate terminal by an SAE signal, while the gate terminal of the fourth transistor 54 is controlled by the battery voltage signal Vbat.

Several variants of the electronic circuit may be provided to enable charging or reading a floating-gate memory structure forming part of the electronic circuit within the scope of the claims.

1. An electronic circuit having a floating-gate memory structure, which comprises from a first input terminal (T) a first transistor (1) with a large floating gate (FG), and from a second input terminal (B) a second transistor (2) with a smaller floating gate (FG) than the first transistor (1), the first transistor (1) being connected in series via its floating gate (FG) to the floating gate (FG) of the second transistor (2), said electronic circuit being arranged so as to read and load the floating-gate memory structure, characterised in that the first transistor is converted into the form of a MOS-type transistor to serve directly as a transistor for reading the floating-gate memory structure.

2. The electronic circuit as claimed in claim 1, characterised in that the electronic circuit is integrated with the floating-gate memory structure in a P-type silicon substrate, and in that the first transistor (1) for implementing a first capacitor of the memory structure is converted into a PMOS-type transistor with a source connected to the substrate connected to the first input terminal (T) of the memory structure, and a drain enabling reading of the state-of-charge of the memory structure in connection with a read unit (30).

3. The electronic circuit according to claim 2, characterised in that the first transistor (1) with a large coupling capacitance (Cc) configured as a read transistor allows interfacing this transistor in the read mode by means of protection transistors, where the parasitic capacitive charges of these protection transistors do not influence the coupling of the first input terminal (T) or of the second input terminal (B) on the floating gate (FG), and in that the size of the read transistor allows significantly reducing the read offset.

4. The electronic circuit according to claim 2, characterised in that the first transistor (1) of the memory structure is converted into a PMOS-type transistor in order to be directly a transistor for reading the state-of-charge of the floating gate of the memory structure in order to avoid the use of an original read transistor having an associated parasitic capacitance, so as to increase the coupling factor of a programming voltage (Vprog) and thus to reduce the value of the programming voltage (Vprog) necessary to obtain a given floating-gate voltage (FG).

5. The electronic circuit according to claim 1, characterised in that the surface ratio between the two PMOS transistors implementing integrated first and second capacitors Cc and Ct of the electronic circuit is greater than 10 times.

6. The electronic circuit according to claim 5, characterised in that the first PMOS transistor (1) is made with a width w equal to 2.24 μm and a length l equal to 1.75 μm, which gives a surface area at the floating gate in the range of 3.92 μm², and in that the second PMOS transistor (2) is made over a width w equal to 0.65 μm and over a length l equal to 0.5 μm, which gives a surface area at the floating gate in the range of 0.325 μm², which is more than 12 times smaller than the surface area of the first PMOS transistor (1).

7. The electronic circuit according to claim 1, characterised in that a read unit (30) is connected to the drain of the first PMOS transistor (1) so as to determine the state-of-charge of the floating-gate memory structure (FG).

8. The electronic circuit according to claim 7, characterised in that a first N DEMOS type transistor (3, 3′) of the read unit (30) is connected by a drain to the drain of the first PMOS transistor (1).

9. The electronic circuit according to claim 1, characterised in that in order to perform a programming of the floating gate (FG) of the memory structure, two PMOS type transistors (21, 22) connected in series connect on one side a programming voltage terminal (Vprog), and on the other side the second input terminal (B) of the floating-gate memory structure (FG) in order to perform charging through the second PMOS transistor (2) with a small capacitance (Ct) by tunnel effect, in that the first PMOS transistor (21) is connected via a source and a substrate to the programming terminal (Vprog), while a drain of the first PMOS transistor (21) is connected to a source and a substrate of the second PMOS transistor (22), a gate of which is biased by a battery voltage (Vbat), and in that the first PMOS transistor (21) serves as a switch for connecting the programming terminal to the second input terminal (B), if the voltage on the gate of the first PMOS transistor (21) is at least at a voltage equivalent to or lower than the battery voltage (Vbat) lower than a programming voltage (Vprog).

10. The electronic circuit according to claim 1, characterised in that it comprises two PMOS type transistors connected in series (11, 12) connecting on one side the programming voltage terminal (Vprog), and on the other side the first input terminal (T) of the floating-gate memory structure (FG), in that the first PMOS transistor (11) is connected by a source and a substrate to the programming terminal (Vprog), while a drain of the first PMOS transistor (11) is connected to a source and a substrate of the second PMOS transistor (12), a gate of which is biased by a battery voltage (Vbat), and in that the first PMOS transistor (11) can be controlled on a gate to be rendered conductive or preferably non-conductive so as not to have a connection with the programming voltage terminal (Vprog) if a drain of the second PMOS transistor (12) is connected to the first input terminal (T) of the first PMOS transistor (1) with a high coupling capacitance.

11. The electronic circuit according to claim 1, characterised in that it comprises two pairs of NMOS type transistors (13, 14; 23, 24) connected in series in cascode respectively from the input terminals (T, B) and connected to a ground terminal (Vss), in that the first NMOS transistor (13, 23) of each pair is a DEMOS transistor biased on a gate by a battery voltage (Vbat), while the second transistor (14, 24) of each pair is an NMOS type transistor respectively controlled on a gate by a control signal (W1, W2).

12. The electronic circuit according to claim 1, characterized in that it comprises two floating-gate memory structures (FG, FG′) inversely connected in parallel between the first input terminal (T) and the second input terminal (B), in that from the first input terminal (T), the first PMOS transistor (1) is provided with a large first floating gate (FG), in that from the second input terminal (B), the second PMOS transistor (2) is provided with a smaller first floating gate (FG) than the first capacitor (1), in that from the second input terminal (B), a third PMOS transistor (42) is provided with a large second floating gate (FG′), and in that from the first input terminal (T), a fourth PMOS transistor (41) is provided with a smaller second floating gate (FG′) than the third PMOS transistor (42).

13. The electronic circuit according to claim 12, characterised in that the read unit (30) comprises a first DEMOS transistor (31) connected by a drain to the drain of the first PMOS read transistor (1), and a second DEMOS transistor (32) connected by a drain to a drain of a second PMOS read transistor (2) of the third capacitor (42), and in that the read unit (30) is configured to output at least one signal (pol-bit-out) of the state-of-charge of the floating gates.
